(19) United States
(12) Patent Application Publication
(10) Pub. No.: US 2009/0283811 A1
(43) Pub. Date: Nov. 19, 2009

(54) Flash memory device and methods of forming the same

(75) Inventors: Jae-Duk Lee, Seongnam-si (KR); Choong-Ho Lee, Yongin-si (KR)

Correspondence Address: HARNESS, DICKEY & PIERCE, P.L.C., P.O. BOX 8910, RESTON, VA, 20195, US

(73) Assignee: SAMSUNG ELECTRONICS CO., LTD.

(21) Appl. No.: 12/385,042

(22) Filed: Mar. 30, 2009

(30) Foreign Application Priority Data
May 16, 2008 (KR) 10-2008-0045271

(51) Int. Cl. H01L 29/788

(52) U.S. Cl. 257/314; 257/E29.3

(57) ABSTRACT

A flash memory device and/or methods of forming the flash memory device are provided, the flash memory device including a charge storage gate, a gate pattern over the charge storage gate, and a charge storage metal layer disposed between a side surface of the charge storage gate and the gate pattern. The methods include forming a preliminary charge storage gate pattern and forming a metal layer over a side surface of the preliminary charge storage gate pattern.

### PRIORITY STATEMENT

This U.S. non-provisional patent application claims the benefit of priority under 35 U.S.C. §119 from Korean Patent Application No. 2008-45271, filed on May 16, 2008, the entire contents of which are hereby incorporated by reference.

### BACKGROUND OF THE INVENTION

1. Field

Example embodiments relate to a flash memory device including a charge storage gate and/or methods of forming the same.

2. Description of Related Art

Semiconductor devices may include a variety of unit devices. For example, the semiconductor device may include a switching device for operation. The switching device may include a transistor. The transistor may include source/drain regions formed on a substrate, a channel region between the source/drain regions, a gate insulating layer and a gate electrode that are sequentially stacked on the channel region. If a voltage greater than a threshold voltage is applied to the gate electrode, a channel electrically connecting the source/drain regions is formed on the channel region. Contrarily, if a voltage less than the threshold voltage is applied to the gate electrode, the source/drain regions may be electrically disconnected. Resistance of the channel may be controlled by a voltage applied to the gate electrode.

The gate electrode may include a doped polysilicon. The polysilicon may be used to control the work function of the gate electrode by controlling the type and/or concentration of an injected dopant. The polysilicon may be used to establish a desired magnitude for the work function of the gate electrode. However, if a voltage is applied to a gate electrode including polysilicon, a depletion region may be formed in the polysilicon. The depletion region may have an additional capacitance. For example, in a flash memory device, if a voltage is applied to a control gate electrode, a depletion region may be formed in a floating gate. If an unnecessary capacitance is formed in the floating gate by the depletion region, a coupling ratio of a flash memory device is reduced. As a result, a loss of efficiency of a device may occur. Moreover, because a transistor may malfunction due to the depletion region as integration of a semiconductor device increases, reliability of the semiconductor device may be degraded.

### SUMMARY

Example embodiments relate to a flash memory device including a charge storage gate and/or methods of forming the same.

The flash memory device according to example embodiments may include a substrate including an active region defined by a device isolation layer, a gate pattern extending across the active region, and a charge storage gate disposed at an intersection between the gate pattern and the active region. The charge storage gate includes a top surface, a side surface and a bottom surface. The device further includes a charge storage metal layer interposed between a side surface of the charge storage gate and the gate pattern, and an intergate dielectric layer disposed between a top surface of the charge storage gate and the gate pattern, between the charge storage metal layer and the gate pattern, and between the device isolation layer and the gate pattern.

Some example embodiments provide a method of forming a flash memory device. The method may include forming a device isolation layer defining an active region on a substrate and a charge storage pattern that extends onto the active region. The charge storage pattern includes silicon. The method may further include forming a conductive pattern including metal on a side surface of the charge storage pattern, forming a dielectric layer on the charge storage pattern, the conductive pattern and the device isolation layer, forming a gate conductive layer on the dielectric layer, and patterning the gate conductive layer, the dielectric layer, the conductive pattern and the charge storage pattern to form a gate pattern which extends to cross the active region, an intergate dielectric layer, a charge storage metal layer and a charge storage gate.

### BRIEF DESCRIPTION OF THE FIGURES

The accompanying figures are included to provide a further understanding of example embodiments, and are incorporated in and constitute a part of this specification. The drawings illustrate example embodiments and, together with the description, serve to explain principles of the present invention. In the figures:

FIG. 1 is a top plan view of a flash memory device according to an example embodiment.

FIGS. 2 through 10 are perspective views taken along the line I-I′ of FIG. 1 illustrating a flash memory device and a method of forming a flash memory device according to an example embodiment.

FIGS. 11 through 13 are perspective views taken along the line I-I′ of FIG. 1 illustrating a flash memory device and a method of forming a flash memory device according to another example embodiment.

FIGS. 14 through 22 are perspective views taken along the line I-I′ of FIG. 1 illustrating a flash memory device and a method of forming a flash memory device according to yet another example embodiment.

FIGS. 23 through 25 are perspective views taken along the line I-I′ of FIG. 1 illustrating a flash memory device and a method of forming a flash memory device according to a further example embodiment.

FIG. 26 is a perspective view of a flash memory device according to a comparative example for comparing with a flash memory device according to another example embodiment.

FIG. 27 is a block diagram of an electronic device including a flash memory device according to an example embodiment.

FIG. 28 is a block diagram of a memory system including a flash memory device according to an example embodiment.

### DETAILED DESCRIPTION OF PREFERRED EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first region/layer could be termed a second region/layer, and, similarly, a second region/layer could be termed a first region/layer without departing from the teachings of the disclosure.

The terminology used herein is for the purpose of describing particular embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Embodiments of the present invention may be described with reference to cross-sectional illustrations, which are schematic illustrations of idealized embodiments of the present invention. As such, variations from the shapes of the illustrations, as a result, for example, of manufacturing techniques and/or tolerances, are to be expected. Thus, embodiments of the present invention should not be construed as limited to the particular shapes of regions illustrated herein, but are to include deviations in shapes that result from, e.g., manufacturing. For example, a region illustrated as a rectangle may have rounded or curved features. Thus, the regions illustrated in the figures are schematic in nature and are not intended to limit the scope of the present invention.

In the drawings, the thickness of layers and regions are exaggerated for clarity. It will also be understood that when an element such as a layer, region or substrate is referred to as being “on” or “onto” another element, it may lie directly on the other element or intervening elements or layers may also be present. Like reference numerals refer to like elements throughout the Specification.

Spatially relatively terms, such as “beneath,” “below,” “above,” “upper,” “top,” “bottom” and the like, may be used to describe an element and/or feature's relationship to another element(s) and/or feature(s) as, for example, illustrated in the figures. It will be understood that the spatially relative terms are intended to encompass different orientations of the device in use and/or operation in addition to the orientation depicted in the figures. For example, when the device in the figures is turned over, elements described as below and/or beneath other elements or features would then be oriented (rotated 90 degrees or at other orientations) and the spatially relative descriptors used herein interpreted accordingly. As used herein, “height” refers to a direction that is generally orthogonal to the faces of a substrate.

Example embodiments relate to a flash memory device including a charge storage gate and/or methods of forming the same.

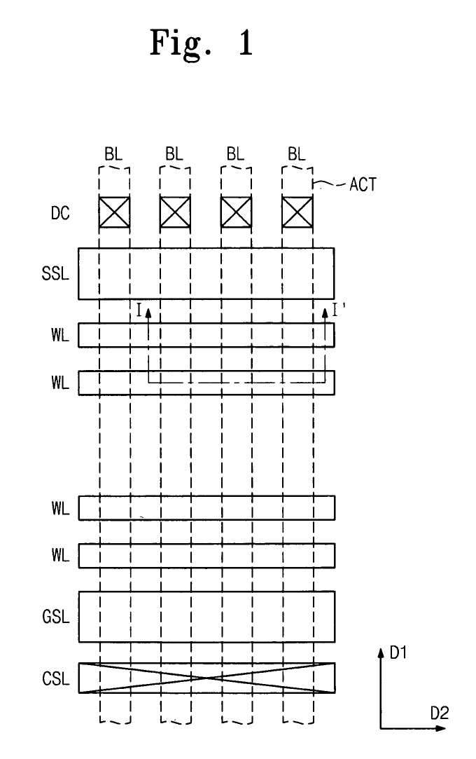

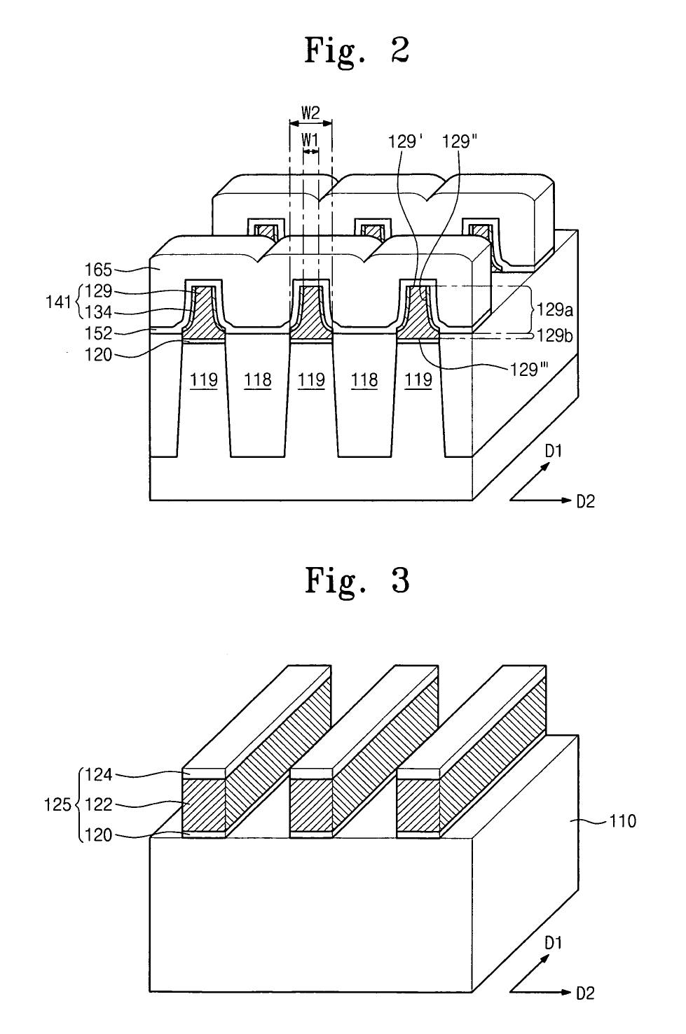

FIG. 1 is a top plan view of a flash memory device according to an example embodiment. FIG. 2 is a perspective view taken along the line I-I′ of FIG. 1 illustrating a flash memory device according to an example embodiment.

Referring to FIGS. 1 and 2, a flash memory device according to an example embodiment will be described.

An active region 119 (ACT) defined by a device isolation layer 118 on a substrate 110 may extend in a first direction (D1). A bit line (BL) may extend above the active region 119 (ACT). The bit line (BL) and the active region 119 (ACT) may be electrically connected to each other through a bit line contact (DC). Word lines (WL) may extend in a second direction (D2) crossing the first direction (D1). A string selection line (SSL) may be disposed between the word lines (WL) and the bit line contact (DC). A ground selection line (GSL) may be positioned apart from the string selection line (SSL) by the word lines (WL). A common source line (CSL) may be positioned adjacent to the ground selection line (GSL).

Each of the word lines (WL) may include a gate pattern 165. The gate pattern 165 may include a doped polysilicon, metal and/or a metal silicide. A charge storage gate 129 may be disposed on the active region 119 crossed by the gate pattern 165. That is, the charge storage gate 129 may be interposed between the gate pattern 165 and the active region 119. The charge storage gate 129 may include silicon (e.g., doped polysilicon). The charge storage gate 129 may include a top surface 129′, a side surface 129″ and a bottom surface 129′″. The side surface 129″ of the charge storage gate 129 may be scalloped. The charge storage gate 129 may include an upper region 129a having a first width (W1) and a lower region 129b having a second width (W2). The first width (W1) may be narrower (or less) than the second width (W2). Thus, the charge storage gate 129 may have a line width smaller than a resolution of a conventional photolithography process. The first width (W1) may be equal to or smaller than a size of a depletion region formed in the charge storage gate 129 by a voltage applied to the gate pattern 165, if the gate pattern 165 is directly in contact with the charge storage gate 129. For example, the first width (W1) may be equal to, or smaller, than two times a distance that the depletion region is from a surface of the charge storage gate 129.

The widths (W1, W2) may cross (and, optionally extend substantially perpendicular to) the first direction (D1). The lower region 129b of the charge storage gate 129 may be covered with the device isolation layer 118. A side surface of the upper region 129a of the charge storage gate 129 may be covered with a charge storage metal layer 134 and the top surface 129′ of the charge storage gate 129 may be in contact with an intergate dielectric layer 152. The charge storage gate 129 and the charge storage metal layer 134 may collectively form a charge gate structure 141.

The charge storage metal layer 134 may include metal having a work function equal to or greater than about 4 eV. The metal may include at least one of tantalum (Ta), titanium (Ti), cobalt (Co), molybdenum (Mo), nickel (Ni), aluminum (Al), zirconium (Zr), hafnium (Hf), combinations thereof, etc. The charge storage metal layer 134 may include a metal silicide of the materials described above. The intergate dielectric layer 152 may include oxide-nitride-oxide or oxide-high dielectric material-oxide. The intergate dielectric layer 152 may be formed relatively thin such that a more highly-integrated circuit can be formed. The intergate dielectric layer 152 may extend on the charge storage gate 129 and the device isolation layer 118 along the gate pattern 165. The charge storage metal layer 134 may be interposed between the side of the upper region 129a and the intergate dielectric layer 152. A gate insulating layer 120 may be interposed between the active region 119 and the charge storage gate 129. The gate insulating layer 120 may include silicon oxide.

FIGS. 3 through 10 are perspective views taken along the line I-I′ of FIG. 1 illustrating a method of forming a flash memory device according to an example embodiment.

Referring to FIGS. 2 through 10, a method of forming a flash memory device according to an example embodiment will be described.

Referring to FIGS. 3 through 5, a preliminary charge storage pattern 122 including an upper region 122a and a lower region 122b may be formed on an active region 119, and the lower region 122b may be covered with a device isolation layer 118.

Referring to FIG. 3, a substrate 110 may be provided. A gate insulating layer 120 may be formed on the substrate 110. The gate insulating layer 120 may include a silicon oxide. The gate insulating layer 120 may be formed by a thermal oxidation process, an atomic layer deposition (ALD) process or the like. A first conductive layer (not shown) may be formed on the gate insulating layer 120. The first conductive layer may include silicon (e.g., doped polysilicon). A first mask layer (not shown) may be formed on the first conductive layer. The first mask layer may include an insulating material (e.g., silicon nitride). The first mask layer and the first conductive layer are sequentially patterned to form a gate stack 125 including the gate insulating layer 120, the preliminary charge storage pattern 122 and a first mask pattern 124 that are sequentially stacked on the substrate 110. The gate stack 125 may extend in a first direction (D1). The gate stack 125 may have the smallest line width that can be obtained by a conventional photolithography process.

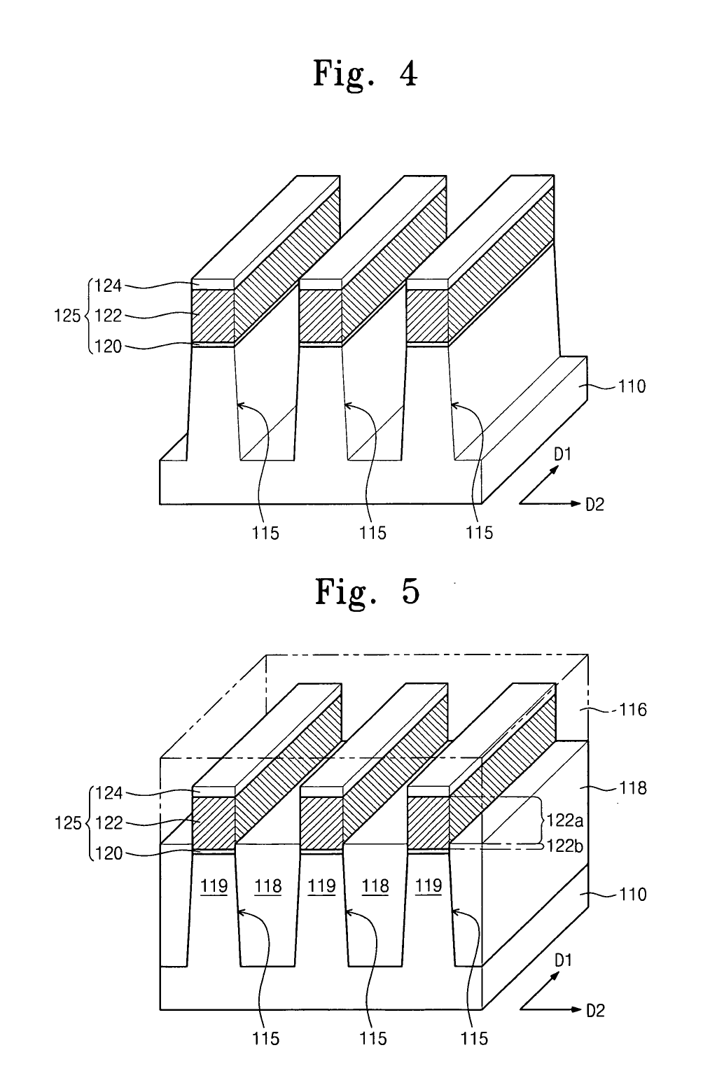

Referring to FIG. 4, the substrate 110 is etched using the gate stack 125 to form a trench 115.

Referring to FIG. 5, a device isolation insulating layer 116 may be formed on the trench 115 and the gate stack 125. The device isolation insulating layer 116 may include an oxide. The device isolation insulating layer 116 may be formed by a chemical vapor deposition (CVD) process. A recess process is applied to the device isolation insulating layer 116 to form the device isolation layer 118 in the trench 115. Alternatively, the device isolation layer 118 may be formed by planarizing the device isolation insulating layer 116 in order to expose a top surface of the preliminary charge storage pattern 122, removing the preliminary charge storage pattern 122, forming a new preliminary charge storage pattern (not shown) and recessing the device isolation insulating layer 116. The new preliminary charge storage pattern may have a width greater than that of the preliminary charge storage pattern 122.

The active region 119 may be defined by the device isolation layer 118. The active region 119 may extend in the first direction (D1) and the gate stack 125 may be disposed on the active region 119. The device isolation layer 118 may be formed covering the lower region 122b of the preliminary charge storage pattern 122 on the active region 119. The upper region 122a of the preliminary charge storage pattern 122 may be exposed.

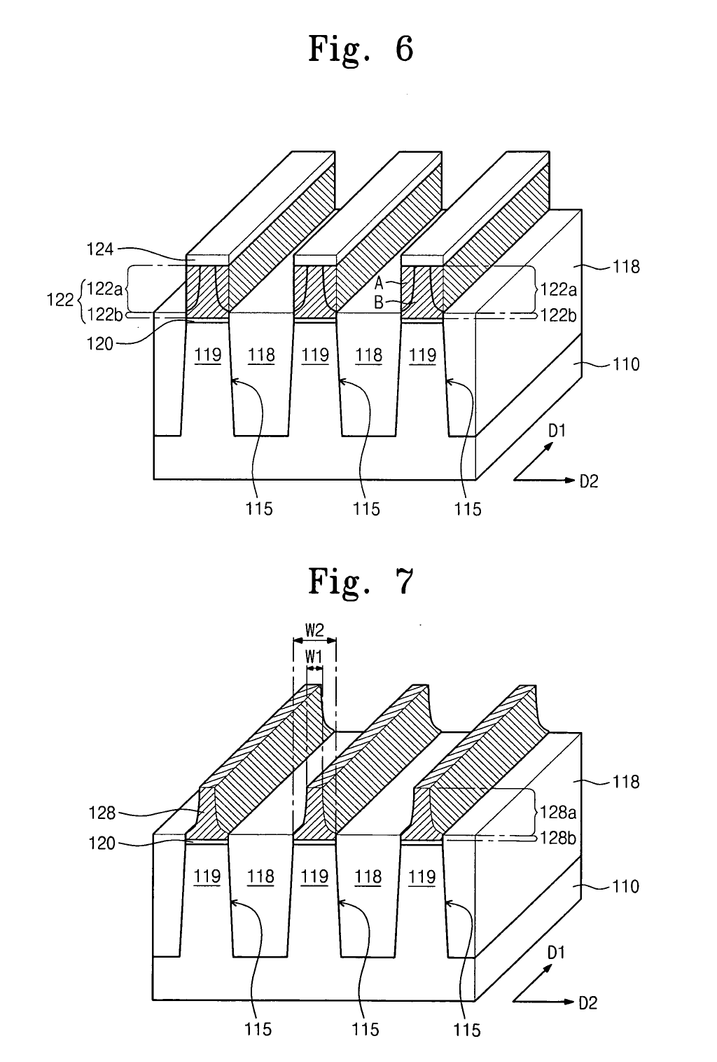

Referring to FIGS. 6 and 7, a charge storage pattern 128 including an upper region 128a having a first width (W1) and a lower region 128b having a second width (W2) wider than the first width (W1) may be formed.

Referring to FIG. 6, an ion implantation process may be applied to the upper region 122a. During the ion implantation process, a top surface of the preliminary charge storage pattern 122 may be protected by the first mask pattern 124, and the lower region 122b may be protected by the device isolation layer 118. That is, ions may be selectively implanted into a side surface of the upper region 122a. A first region (A) into which the ions are selectively implanted may have an etching selectivity with respect to a second region (B) of the preliminary charge storage pattern 122, the first mask pattern 124 and the device isolation layer 118. A size and an etching selectivity of the first region (A) may be controlled by adjusting the energy used during the ion implantation process, the angle at which the ion implantation process is applied, the type of impurity and the quantity of a dose of the impurity.

Referring to FIGS. 6 and 7, the first region (A) is selectively removed to form the charge storage pattern 128. The charge storage pattern 128 may include an upper region 128a having a first width (W1) and a lower region 128b having a second width (W2). The first width (W1) may be narrower (or less) than the second width (W2). Thus, the charge storage pattern 128 may have a line width smaller than a resolution of a conventional photolithography process. A direction of the width may cross (and, optionally extend substantially perpendicular to) the first direction (D1). The first mask pattern 124 may be removed.

The first region (A) may be removed by performing an isotropic etching process. In the isotropic etching process, the preliminary charge pattern 122 may have an etching selectivity with respect to the first mask pattern 124 and the device isolation layer 118. The first region (A) may be selectively removed by controlling the isotropic etching time. The ion implantation process and the isotropic etching may be performed without the first mask pattern 124.

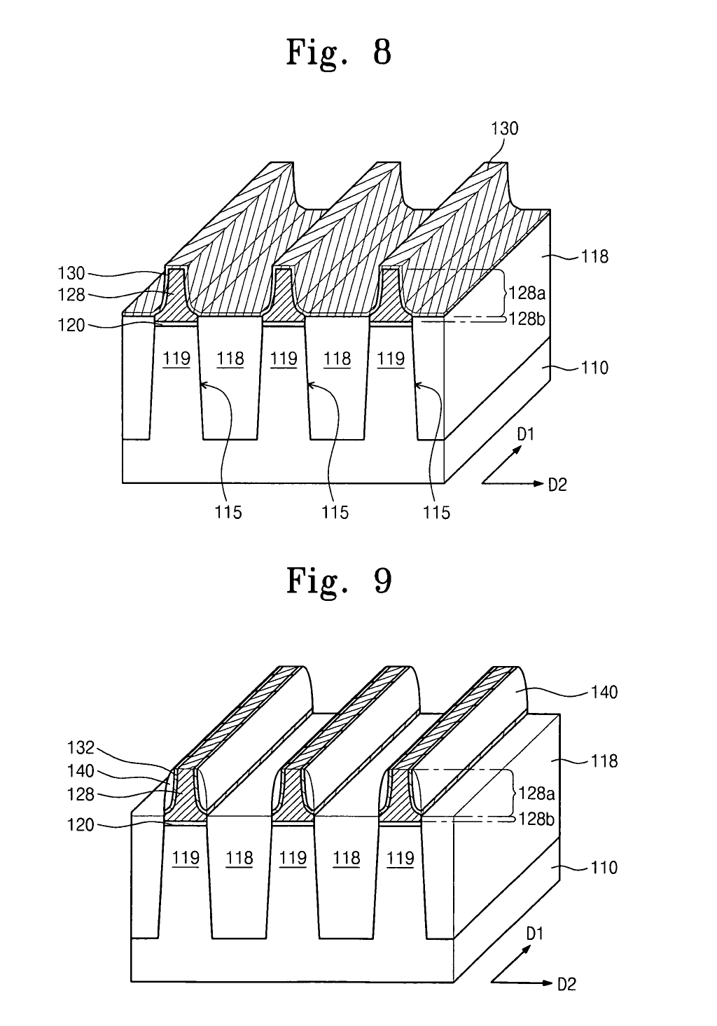

Referring to FIG. 8, a second conductive layer 130 may be formed on the charge storage pattern 128 and the device isolation layer 118. The second conductive layer 130 may include metal. For example, the metal may include a material having a work function equal to, or greater than, 4 eV. The metal may include at least one of tantalum (Ta), titanium (Ti), cobalt (Co), molybdenum (Mo), nickel (Ni), aluminum (Al), zirconium (Zr), hafnium (Hf), combinations thereof, etc.

Referring to FIGS. 8 and 9, a spacer layer (not shown) may be formed on the second conductive layer 130. The spacer layer may be conformally formed on the second conductive layer 130. An anisotropic etching process may be applied to the spacer layer. The anisotropic etching process may be performed in order to expose a top surface of the charge storage pattern 128 and the second conductive layer 130 on the device isolation layer 118. A spacer 140 may be formed on a side surface of the upper region 128a of the charge storage pattern 128 by the anisotropic etching process. An exposed portion of the second conductive layer 130 by the spacer 140 may be removed using the spacer 140 as a mask. The second conductive layer 130 may include a material having an etching selectivity with respect to the spacer 140. Accordingly, a conductive pattern 132 may remain on the side surface of the upper region 128a of the charge storage pattern 128.

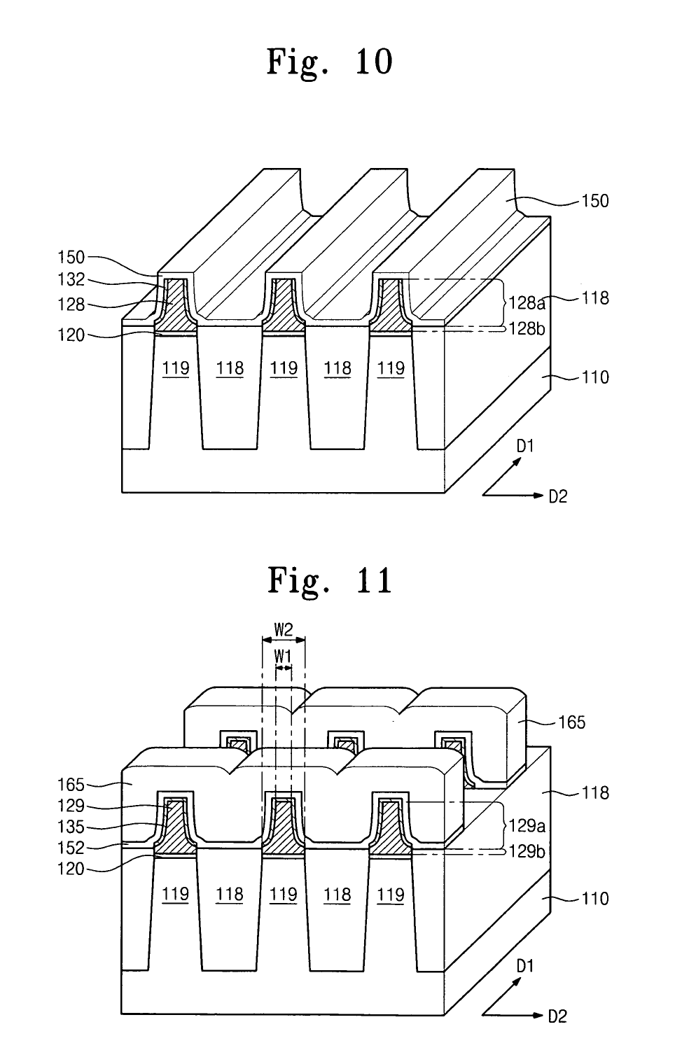

Referring to FIGS. 9 and 10, the spacer 140 may be selectively removed. A dielectric layer 150 may be conformally formed on the charge storage pattern 128 and the device isolation layer 118. The dielectric layer 150 may include oxide-nitride-oxide or oxide-high dielectric material-oxide. The dielectric layer 150 may be formed relatively thin in order to form a highly-integrated device.

Referring to FIGS. 10 and 2, a third conductive layer (not shown) may be formed on the resulting structure. The third conductive layer may include doped polysilicon, metal, and/or metal silicide. The third conductive layer, the dielectric layer 150, the conductive pattern 132 and the charge storage pattern 128 are sequentially patterned to form a charge storage gate 129, a charge storage metal layer 134, an intergate dielectric layer 152 and a gate pattern 165 that are sequentially stacked. The gate pattern 165 may extend in a second direction (D2) crossing (and, optionally extending substantially perpendicular to) the first direction (D1). The charge storage gate 129 may include a top surface 129′, a side surface 129″ and a bottom surface 129′″. The charge storage gate 129 may include an upper region 129a having the first width (W1) and a lower region 129b having the second width (W2). The widths may cross (and, optionally extend substantially perpendicular to) the first direction (D1). The charge storage gate 129 may be interposed between the gate pattern 165 and the active region 119. The intergate dielectric layer 152 may be interposed between the charge storage gate 129 and the gate pattern 165. The charge storage metal layer 134 may be interposed between the side surface of the charge storage gate 129 and the intergate dielectric layer 152.

FIGS. 11 through 13 are perspective views taken along the line I-I′ of FIG. 1 illustrating a flash memory device and a method of forming a flash memory device according to another example embodiment.

Referring to FIGS. 1 and 11, a flash memory device according to another example embodiment will be described. Hereinafter, the description of common features already discussed in the flash memory device of the above example embodiments will be omitted or briefly described for the sake of brevity.

An active region 119 (ACT) defined by a device isolation layer 118 on a substrate 110 may extend in a first direction (D1). Word lines (WL) may extend in a second direction (D2) crossing (and, optionally extending substantially perpendicular to) the first direction (D1).

Each of the word lines (WL) may include a gate pattern 165. A charge storage gate 129 may be disposed on an intersection between the active region 119 and the gate pattern 165. The charge storage gate 129 may include silicon (e.g., doped polysilicon). The charge storage gate 129 may include a top surface, a side surface and a bottom surface. The charge storage gate 129 may include an upper region 129a having a first width (W1) and a lower region 129b having a second width (W2) wider than the first width (W1). The first width (W1) may be equal to, or smaller than, a size of a depletion region formed in the charge storage gate 129 by a voltage applied to the gate pattern 165 if the gate pattern 165 is directly in contact with the charge storage gate 129. For example, the first width (W1) may be equal to, or smaller than, two times the distance that the depletion region is formed from a surface of the charge storage gate 129. The widths (W1, W2) may cross (or extend in) the first direction (D1). The lower region 129b of the charge storage gate 129 may be covered with the device isolation layer 118. The side surface of the upper region 129a and the top surface of the charge storage gate 129 may be covered with a charge storage metal layer 135. The charge storage metal layer 135 may include metal having a work function equal to, or greater than, 4 eV. The metal may include at least one silicide selected from the group consisting of tantalum (Ta), titanium (Ti), cobalt (Co), molybdenum (Mo), nickel (Ni), aluminum (Al), zirconium (Zr), hafnium (Hf), combinations thereof, etc.

An intergate dielectric layer 152 may be interposed between the charge storage metal layer 135 and the gate pattern 165. The intergate dielectric layer 152 may include oxide-nitride-oxide or oxide-high dielectric material-oxide. The intergate dielectric layer 152 may be formed relatively thin in order to form a highly-integrated device. The intergate dielectric layer 152 may extend along the gate pattern 165 on the charge storage metal layer 135 and the device isolation layer 118. A gate insulating layer 120 may be interposed between the active region 119 and the charge storage gate 129.

Referring to FIGS. 11 through 13, a method of forming a flash memory device according to another example embodiment. The description of common features already discussed above will be omitted or briefly described for the sake of brevity.

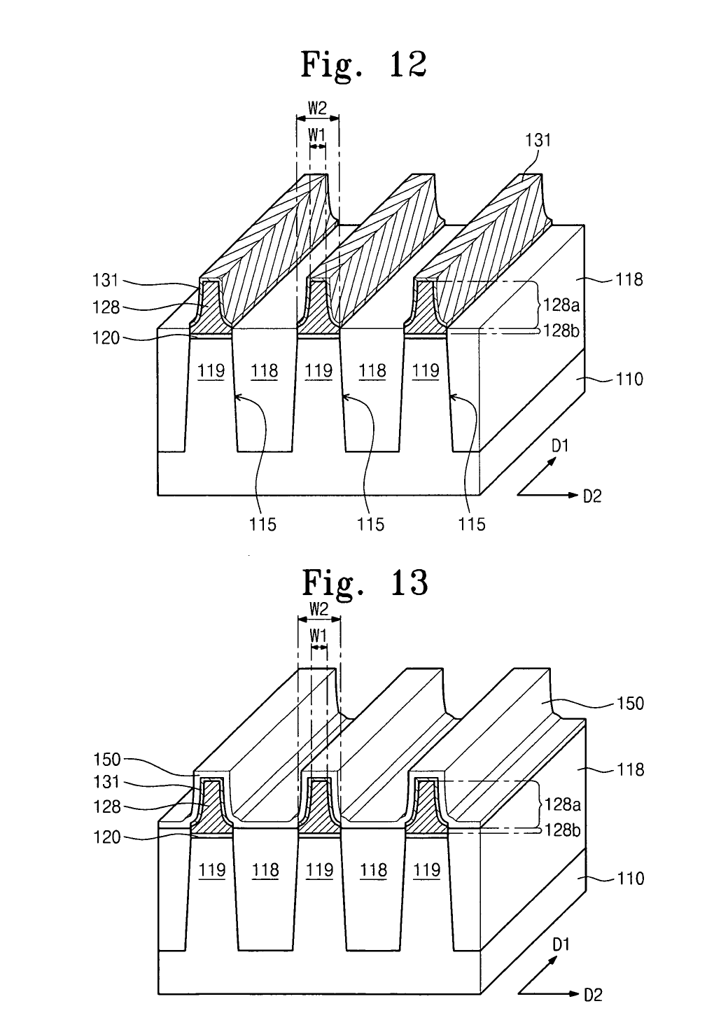

Referring to FIG. 12, a second conductive layer 131 may be selectively formed on an exposed top surface and an exposed side surface of the charge storage pattern 128 by applying a silicidation process to a resulting structure of FIG. 7. The second conductive layer 131 may include at least one silicide selected from the group consisting of tantalum (Ta), titanium (Ti), cobalt (Co), molybdenum (Mo), nickel (Ni), aluminum (Al), zirconium (Zr), hafnium (Hf), combinations thereof, etc. The silicidation process may include performing a deposition process by depositing at least one of metal (e.g., tantalum (Ta), titanium (Ti), cobalt (Co), molybdenum (Mo), nickel (Ni), aluminum (Al), zirconium (Zr), hafnium (Hf), combinations thereof, etc.) and an annealing process. Thus, the second conductive layer 131 may be selectively formed on a surface of the charge storage pattern 128 including silicon. Any remaining metal material that does not react may be removed by a cleaning process.

Referring to FIG. 13, a dielectric layer 150 may be conformally formed on the charge storage pattern 128 that is covered with the second conductive layer 131 and the device isolation layer 118. The dielectric layer 150 may include oxide-nitride-oxide or oxide-high dielectric material-oxide. The dielectric layer 150 may be formed relatively thin in order to form a highly-integrated device.

Referring to FIGS. 13 and 11, a third conductive layer (not shown) may be formed on the resultant structure. For example, the third conductive layer may include doped polysilicon, metal, and/or a metal silicide. The third conductive layer, the dielectric layer 150, the second conductive layer 131 and the charge storage pattern 128 are sequentially patterned to form a charge storage gate 129, a charge storage metal layer 135, an intergate dielectric layer 152 and a gate pattern 165 that are sequentially stacked. The gate pattern 165 may extend in a second direction (D2) crossing (and, optionally extend substantially perpendicular to) the first direction (D1). The charge storage gate 129 may include a top surface, a side surface and a bottom surface. The charge storage gate 129 may include an upper region 129a having the first width (W1) and a lower region 129b having the second width (W2). The widths (W1, W2) may cross the first direction (D1). The charge storage gate 129 may be interposed between the gate pattern 165 and the active region 119. The intergate dielectric layer 152 may be interposed between the charge storage gate 129 and the gate pattern 165. The charge storage metal layer 135 may be interposed between the side surface of the charge storage gate 129 and the intergate dielectric layer 152 and between the top surface of the charge storage gate 129 and the intergate dielectric layer 152.

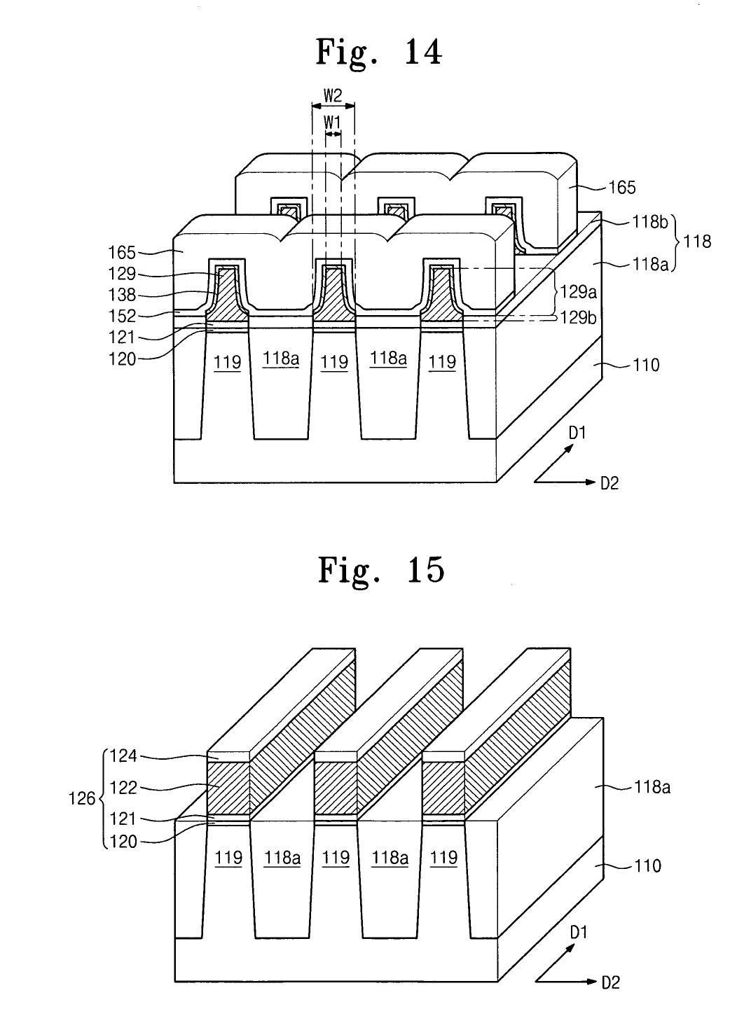

FIGS. 14 through 22 are perspective views taken along the line I-I′ of FIG. 1 illustrating a flash memory device and a method of forming a flash memory device according to yet another example embodiment.

Referring to FIGS. 1 and 14, a flash memory device according to yet another example embodiment will be described. Hereinafter, the description of common features already discussed in the flash memory device of the above embodiments will be omitted or briefly described for the sake of brevity.

An active region 119 (ACT) defined by a device isolation layer 118 on a substrate 110 may extend in a first direction (D1). The device isolation layer 118 may include a first device isolation layer 118a and a second device isolation layer 18b. Word lines (WL) may extend in a second direction (D2) crossing (and, optionally extending substantially perpendicular to) the first direction (D1).

Each of the word lines (WL) may include a gate pattern 165. A charge storage gate 129 including silicon may be disposed on the active region 119 at the point crossed by (or intersected) the gate pattern 165. The charge storage gate 129 may include a top surface, a side surface and a bottom surface. The charge storage gate 129 may include an upper region 129a having a first width (W1) and a lower region 129b having a second width (W2) wider than the first width (W1). The first width (W1) may be equal to, or smaller than, a size of a depletion region formed in the charge storage gate 129 by a voltage applied to the gate pattern 165 if the gate pattern 165 is directly in contact with the charge storage gate 129. For example, the first width (W1) may be equal to, or smaller than, two times the distance where the depletion region is formed from a surface of the charge storage gate 129. The widths (W1, W2) may cross (and, optionally extend in) the first direction (D1). The bottom surface may be in contact with a bottom conductive layer 121. The bottom conductive layer 121 may include metal. The metal may include at least one selected from the group consisting of tantalum (Ta), titanium (Ti), cobalt (Co), molybdenum (Mo), nickel (Ni), aluminum (Al), zirconium (Zr), hafnium (Hf), combinations thereof, etc. The bottom conductive layer 121 may also include silicide of the metals described above. The lower region 129b of the charge storage gate 129 may be covered with the device isolation layer 118. Alternatively, the device isolation layer 118 may expose an entire side surface of the charge storage gate 129 but may cover the entire bottom conductive layer 121. A side surface and a top surface of the upper region 129a of the charge storage gate 129 may be covered with a charge storage metal layer 138. The charge storage metal layer 138 may include metal having a work function equal to, or greater than, 4 eV. The metal may include at least one silicide of tantalum (Ta), titanium (Ti), cobalt (Co), molybdenum (Mo), nickel (Ni), aluminum (Al), zirconium (Zr), hafnium (Hf), combinations thereof, etc. The charge storage metal layer 138 may include silicide of metals described above.

An intergate dielectric layer 152 may be interposed between the charge storage metal layer 138 and the gate pattern 165. The intergate dielectric layer 152 may include oxide-nitride-oxide or oxide-high dielectric material-oxide. The intergate dielectric layer 152 may be formed relatively thin in order to form a highly-integrated device. A gate insulating layer 120 may be interposed between the active region 119 and the bottom conductive layer 121.

Referring to FIGS. 14 through 22, a method of forming a flash memory device according to a yet another example embodiment will be described.

Referring to FIG. 15, a substrate 110 may be provided. A first device isolation layer 118a may be formed in the substrate 110 by a shallow trench isolation (STI) process. The first device isolation layer 118a may include an oxide. An active region 119 extending in a first direction (D1) may be defined by the first device isolation layer 118a. A gate insulating layer 120 may be formed on the active region 119. The gate insulating layer 120 may include a silicon oxide. The gate insulating layer 120 may be formed by a thermal oxidation process, an atomic layer deposition (ALD) or similar process. A first conductive layer (not shown) may be formed on the gate insulating layer 120 and the first device isolation layer 118a. The first conductive layer may include metal. The metal may include at least one selected from the group consisting of tantalum (Ta), titanium (Ti), cobalt (Co), molybdenum (Mo), nickel (Ni), aluminum (Al), zirconium (Zr), hafnium (Hf), combinations thereof, etc. The first conductive layer may silicide of the metals described above. A second conductive layer (not shown) may be formed on the first conductive layer. The second conductive layer may include silicon (e.g., doped polysilicon). A first mask layer (not shown) may be formed on the second conductive layer. The first mask layer may include an insulating material (e.g., a silicon nitride). A gate stack 126 is formed including the gate insulating layer 120, a bottom conductive layer 121, a first preliminary charge storage pattern 122 and a first mask pattern 124 that are sequentially stacked on the active region 119 by a patterning process. The gate stack 26 may extend in the first direction (D1). The gate stack 126 may have the smallest line width that can be obtained by a conventional photolithography process.

Referring to FIG. 16, a device isolation layer 117 may be formed on the gate stack 126 and the first device isolation layer 118a. The device isolation insulating layer 117 may include oxide and may be formed by a chemical vapor deposition (CVD) process. A recess process is applied to the device isolation insulating layer 117 to form a second device isolation layer 118b. The second device isolation layer 118b may cover a lower region 122b of the preliminary charge storage pattern 122 on the active region 119. An upper region 122a of the preliminary charge storage pattern 122 may be exposed. Alternatively, the second device isolation layer 118b may expose an entire side surface of the preliminary charge storage pattern 122 but cover the entire bottom conductive layer 121.

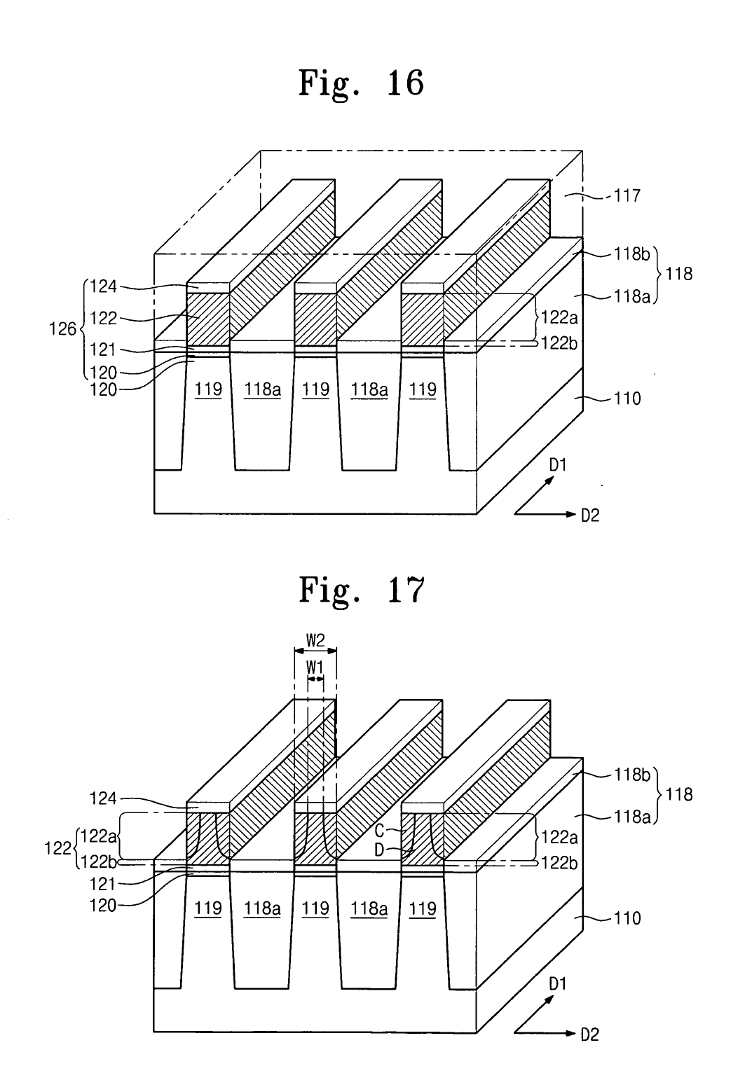

Referring to FIG. 17, an oxidation process may be applied to the resulting structure. An exposed surface of the upper region 122a of the preliminary charge storage pattern 122 may be selectively oxidized. A first region (C) that is selectively oxidized by the oxidation process may have an etching selectivity with respect to a second region (D) of the preliminary charge storage pattern 122. A top surface of preliminary charge storage pattern 122 may be protected by the first mask pattern 124. The lower region 122b of the preliminary charge storage pattern 122 may be protected by the second device isolation layer 118b. The side surface of the upper region 122a may be selectively oxidized.

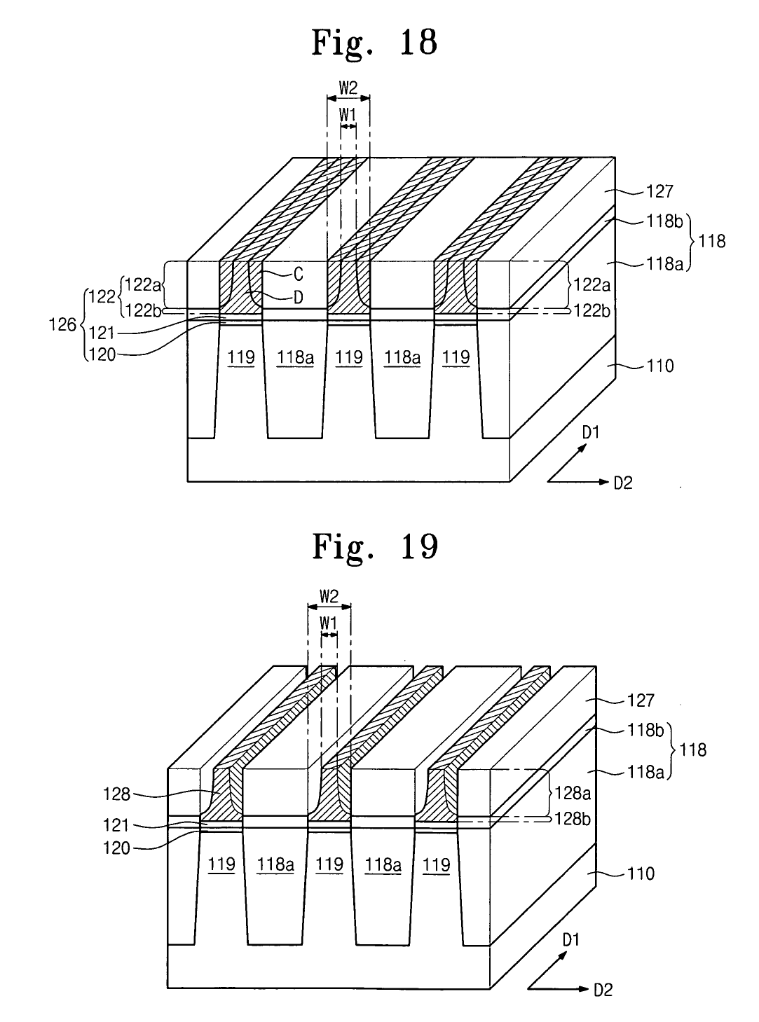

Referring to FIGS. 18 and 19, the first mask pattern 124 may be removed. A second mask pattern 127 burying a space between the preliminary charge storage patterns 122 may be formed. The second mask pattern 127 may include a silicon nitride. The second device isolation layer 118b may be protected, and a top surface of the preliminary charge storage pattern 122 may be exposed by the second mask pattern 127. The first region (A) may be selectively etched to form a charge storage pattern 128. The charge storage pattern 128 may include an upper region 128a having a first width (W1) and a lower region 128b having a second width (W2). The first width (W1) may be smaller than the second width (W2). The charge storage pattern 128 may have a line width smaller than a resolution of a conventional photolithography process. The widths (W1, W2) may cross the first direction (D1).

The first region (C) may be formed by an ion implantation process. The first region (C) may be removed by an isotropic etching process.

Referring to FIGS. 19 and 20, a third conductive layer 136 may be formed on the charge storage pattern 128 and the second device isolation layer 118b. The third conductive layer 136 may include metal. The metal may include a material having a work function equal to, or greater than, 4 eV. The metal may include at least one selected from the group consisting of tantalum (Ta), titanium (Ti), cobalt (Co), molybdenum (Mo), nickel (Ni), aluminum (Al), zirconium (Zr), hafnium (Hf), combinations thereof, etc.

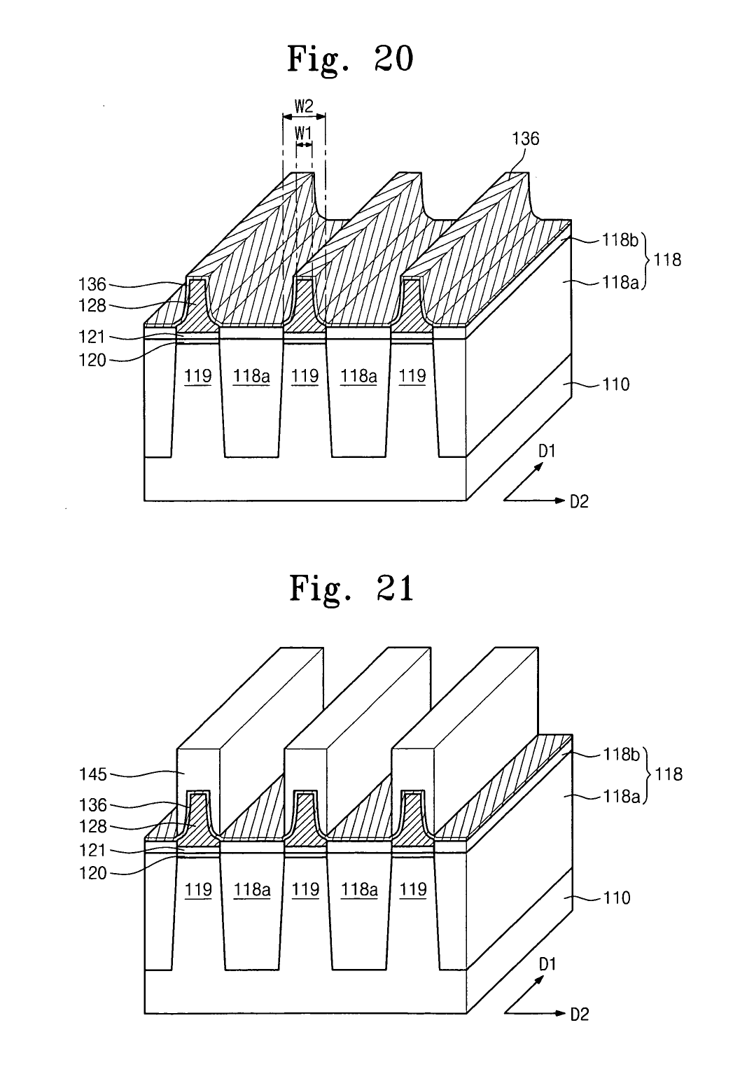

Referring to FIG. 21, a mask layer (not shown) may be formed on the third conductive layer 136. The mask layer is patterned to form a third mask pattern 145 exposing the third conductive layer 136 on the second device isolation layer 118b while covering the charge storage pattern 128. The third mask pattern 145 may be formed by a photolithography process.

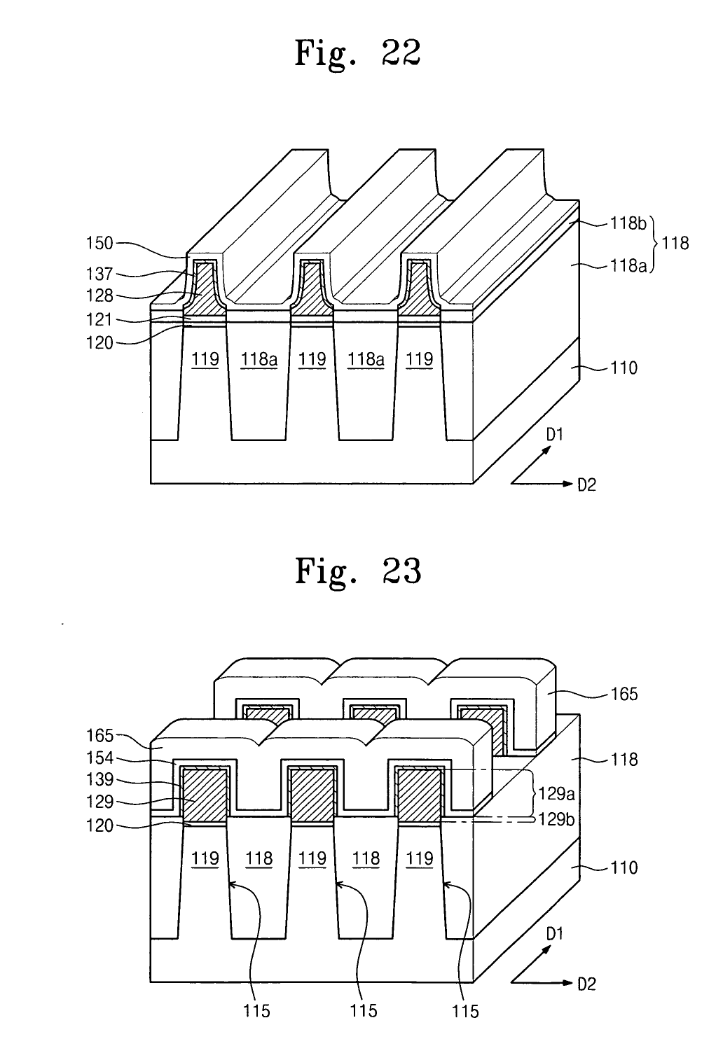

Referring to FIGS. 21 and 22, the exposed third conductive layer 136 exposed on the second device isolation layer 118b may be removed using the third mask pattern 145. The third conductive layer 136 has an etching selectivity with respect to the third mask pattern 145 and the second device isolation layer 118b. The third conductive layer 136 may be selectively removed to form a conductive pattern 137 on a side surface and a top surface of the charge storage pattern 128. The third mask pattern 145 may be removed.

A dielectric layer 150 may be conformally formed on a top surface and a side surface of the charge storage pattern 128 covered with the conductive pattern 137 and the second device isolation layer 118b. The dielectric layer 150 may include oxide-nitride-oxide or oxide-high dielectric material-oxide. The dielectric layer 150 may be formed relatively thin in order to form a highly-integrated device.

Referring to FIGS. 22 and 14, a conductive layer (not shown) may be formed on the resulting structure. The fourth conductive layer may include doped polysilicon, metal, and/or metal silicide. The fourth conductive layer, the dielectric layer 150, the conductive pattern 137 and the charge storage pattern 128 are sequentially patterned to form a charge storage gate 129, a charge storage metal layer 138, an intergate dielectric layer 152 and a gate pattern 165 that are sequentially stacked. The gate pattern 165 may extend in a second direction (D2) crossing the first direction (D1). The charge storage gate 129 may include a top surface, a side surface and a bottom surface. The charge storage gate 129 may include an upper region 129a having the first width (W1) and a lower region 129b having the second width (W2). The widths may cross the first direction (D1). The charge storage gate 129 may be interposed between the gate pattern 165 and the active region 119. The intergate dielectric layer 152 may be interposed between the charge storage gate 129 and the gate pattern 165. The charge storage metal layer 138 may be interposed between a side surface of the charge storage gate 129 and the intergate dielectric layer 152.

FIGS. 23 through 25 are perspective views taken along the line I-I′ of FIG. 1 illustrating a flash memory device and a method of forming a flash memory device according to a further example embodiment.

Referring to FIGS. 1 and 23, a flash memory device according to a further example embodiment will be described. Hereinafter, the description of common features already discussed in the flash memory device of the above embodiments will be omitted or briefly described for the sake of brevity.

An active region 119 (ACT) defined by a device isolation layer 118 on a substrate 110 may extend in a first direction (D1). Word lines (WL) may extend in a second direction (D2) crossing the first direction (D1).

Each of the word lines (WL) may include a gate pattern 165. A charge storage gate 129 may be disposed on the active region 119 crossed by the gate pattern 165. The charge storage gate 129 may include silicon (e.g., a doped polysilicon). The charge storage gate 129 may include a top surface, a side surface and a bottom surface. The charge storage gate 129 may include an upper region 129a and a lower region 129b. The upper and lower regions 129a and 129b have a same width. The lower region 129b may be covered with the device isolation layer 118. A top surface and a side surface of the upper region 129a of the charge storage gate 129 may be covered with a charge storage metal layer 139. The charge storage metal layer 139 may include metal having a work function equal to, or greater than, 4 eV. The metal may include at least one silicide of tantalum (Ta), titanium (Ti), cobalt (Co), molybdenum (Mo), nickel (Ni), aluminum (Al), zirconium (Zr), hafnium (Hf), combinations thereof, etc. The charge storage metal layer 139 may include silicide of metals described above.

An intergate dielectric layer 154 may be interposed between the charge storage metal layer 139 and the gate pattern 165. The intergate dielectric layer 154 may include oxide-nitride-oxide or oxide-high dielectric material-oxide. The intergate dielectric layer 154 may be formed relatively thin in order to form a highly-integrated device. The intergate dielectric layer 154 may extend along the gate pattern 165 on the charge storage metal layer 139 and the device isolation layer 118. A gate insulating layer 120 may be interposed between the active region 119 and the charge storage gate 129.

Referring to FIGS. 23 through 25, a method of forming a flash memory device according to a further example embodiment will be described.

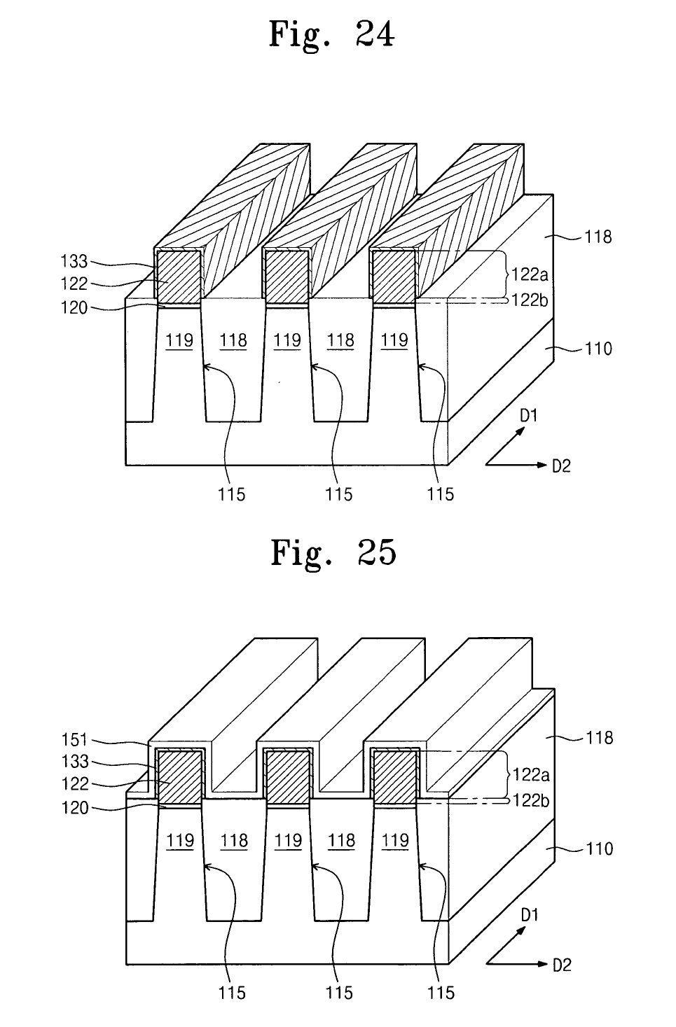

Referring to FIG. 24, a first mask pattern 124 may be removed from the resulting structure of FIG. 5. The first mask pattern 124 is removed to expose a top surface of the preliminary charge storage pattern 122. A second conductive layer 133 may be selectively formed on an exposed top surface of the preliminary charge storage pattern 122 and a side surface of the upper region 122a by performing a silicidation process. The silicidation process may include performing a deposition process of at least one of metal (e.g., tantalum (Ta), titanium (i), cobalt (Co), molybdenum (Mo), nickel (Ni), aluminum (Al), zirconium (Zr), hafnium (Hf), combinations thereof, etc.) and an annealing process. Thus, the second conductive layer 133 may be selectively formed on a surface of the charge storage pattern 122 including silicon. A remaining metal material that does not react may be removed by a cleaning process.

Referring to FIG. 25, a dielectric layer 151 may be conformally formed on the preliminary charge storage pattern 122 covered with the second conductive layer 133 and the device isolation layer 118. The dielectric layer 151 may include oxide-nitride-oxide or oxide-high dielectric material-oxide. The dielectric layer 151 may be formed relatively thin in order to form a highly-integrated device.

Referring to FIGS. 25 and 23, a third conductive layer (not shown) may be formed on the resulting structure. The third conductive layer may include doped polysilicon, metal, and/or metal silicide. The third conductive layer, the dielectric layer 151, the second conductive pattern 133 and the preliminary charge storage pattern 122 are sequentially patterned to form a charge storage gate 129, a charge storage metal layer 139, an intergate dielectric layer 154 and a gate pattern 165 that are sequentially stacked. The gate pattern 165 may extend in a second direction (D2) crossing (or intersecting) the first direction (D1). The charge storage gate 129 may include a top surface, a side surface and a bottom surface. The charge storage gate 129 may include an upper region 129a and a lower region 129b. The upper and lower regions 129a and 129b may have a same width. The charge storage gate 129 may be interposed between the gate pattern 165 and the active region 119. The intergate dielectric layer 154 may be interposed between the charge storage gate 129 and the gate pattern 165. The charge storage metal layer 139 may be interposed between the side surface of the charge storage gate 129 and the intergate dielectric layer 154 and between the top surface of the charge storage gate 129 and the integrate dielectric layer 154.

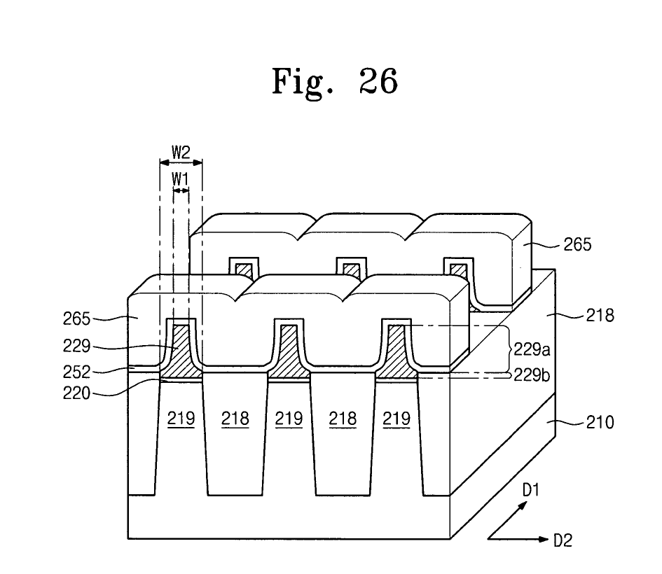

FIG. 26 is a perspective view of a flash memory device according to a comparative example for comparing with a flash memory device according to another example embodiment.

Referring to FIG. 26, a flash memory device according to a comparative example to compare with another example embodiment will be described. Hereinafter, the description of common features already discussed in the flash memory device of the above embodiments will be omitted or briefly described for the sake of brevity.

An active region 219 defined by a device isolation layer 218 on a substrate 210 may extend in a first direction (D1). A gate pattern 265 may extend in a second direction (D2) crossing the first direction (D1). A charge storage gate 229 may be disposed on an intersection where the active region 219 and the gate pattern 265 cross (or intersect) each other. The charge storage gate 229 may include a top surface, a side surface and a bottom surface. The charge storage gate 229 may include an upper region 229a having a first width (W1) and a lower region 229b having a second width (W2). The first width (W1) may be narrower (or less) than the second width (W2). The first width (W1) may be equal to, or smaller than, two times the distance from a surface of the charge storage gate 229 of the depletion region formed in the charge storage gate 229 by a voltage applied to the gate pattern 265 if the gate pattern 265 is in direct contact with the gate pattern 265. The widths (W1, W2) may cross the first direction (D1). The lower region 229b may be covered with the device isolation layer 218. In contrast, a side surface of the upper region 229a of the charge storage gate 229 and the top surface may be in direct contact with an intergate dielectric layer 252.

The intergate dielectric layer 252 may extend along the gate pattern 265 on the charge storage gate 229 and the device isolation layer 218. A gate insulating layer 220 may be interposed between the charge storage gate 229 and the active region 219.

In the comparative example, a gate voltage is applied to the gate pattern 265 to store data in the charge storage gate 229. If the gate voltage is applied, a depletion region may be formed in the charge storage gate 229. The depletion region may be formed from the surface toward the inside of the charge storage gate 229. Because the upper region 229a of the charge storage gate 229 has a narrow width (i.e., W1), in some cases, a depletion region may be formed in the entire upper region 229a. Because the depletion region has an insulation characteristic, a coupling ratio of a device of the comparative example may be rapidly reduced, causing a device to malfunction.

In the example embodiments, if a gate voltage is applied to the gate pattern 165 to store data in the charge storage gate 129, the charge storage metal layers (134, 135, 138, 139) may mitigate a depletion region from being formed in the charge storage gate 129. Thus, the charge storage gate 129 may include an upper region having a width (e.g., first width (W1)) small enough to mitigate interference with an adjacent charge storage gate without reduction of a coupling ratio.

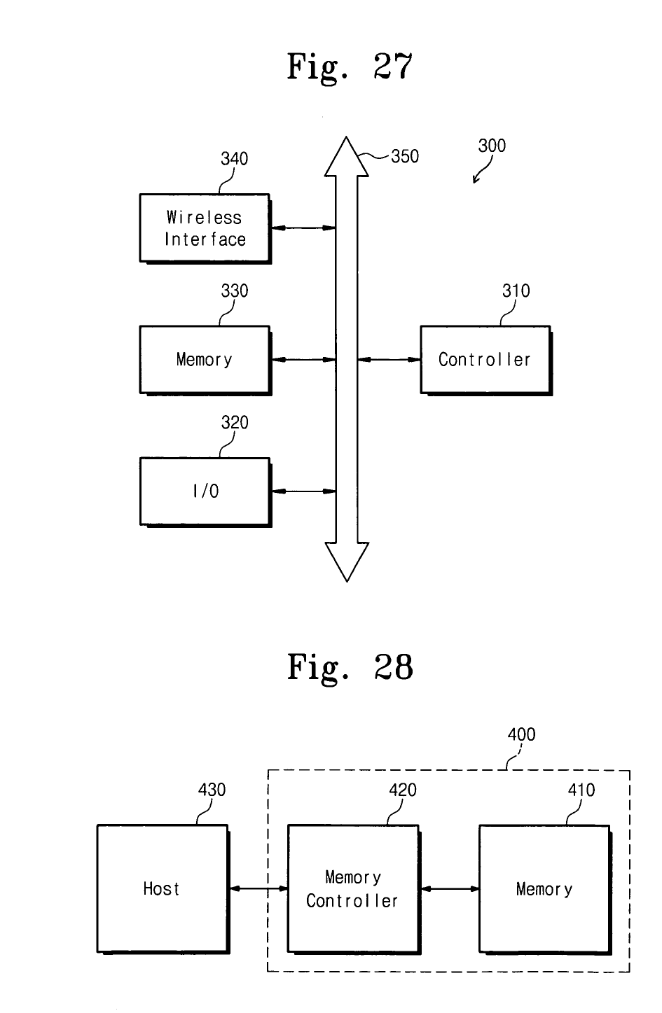

FIG. 27 is a block diagram of an electronic device including a flash memory device according to an example embodiment.

Referring to FIG. 27, an electronic device 300 including a memory device according to an example embodiment will be described. The electronic device 300 may be used in a wireless communication device (e.g., a PDA, a laptop computer, a portable computer, a web tablet, a wireless phone, a cell phone, a digital music player or the like), or a device that can transfer and/or receive information in a wireless environment.

The electronic device 300 may include a controller 310, an input/output device 320 (e.g., a keypad, a keyboard and a display), a memory 330, a wireless interface 340 that are combined with each other through a bus 350. Controller 310 may include a microprocessor, a digital signal process, a microcontroller, or the like. The memory 330 may be used to store an instruction executed by the controller 310. The memory 330 may also be used to store user's data. The memory 330 may include a memory device according to example embodiments.

The electronic device 300 may use the wireless interface 340 to transfer data to a wireless communication network communicating with RF signal or receive data from the network. The wireless interface 340 may include an antenna, a wireless transceiver, etc.

The electronic device 300 according to example embodiments may be used in a communication interface protocol of a third generation communication system (e.g., CDMA, GSM, NADC, E-TDMA, WCDMA, CDMA2000).

FIG. 28 is a block diagram of a memory system including a flash memory device according to an example embodiment.

Referring to FIG. 28, a memory system including a memory device according to an example embodiment will be described.

A memory system 400 may include a memory device 410 and a memory controller 420 to store substantially large amounts of data. The memory controller 420 controls the memory device 410 to read data stored in the memory device 410 or write data to the memory device 410 in response to a request of read/write of a host 430. The memory controller 420 may constitute an address mapping table to map an address provided from the host 430 (a mobile device or a computer system) into a physical address of the memory device 410.

The foregoing is illustrative of example embodiments and is not to be construed as limiting thereof. Although a few example embodiments have been described, those skilled in the art will readily appreciate that many modifications are possible in the embodiments without materially departing from the novel teachings and advantages. Accordingly, all such modifications are intended to be included within the scope of the present invention as defined in the claims. Therefore, it is to be understood that the foregoing is illustrative of the present invention and is not to be construed as limited to example embodiments disclosed, and that modifications to the disclosed embodiments, as well as other embodiments, are intended to be included within the scope of the appended claims. The present invention is defined by the following claims, with equivalents of the claims to be included therein.

1. A flash memory device, comprising:
a substrate including an active region defined by a device isolation layer;
a gate pattern extending across the active region;
a charge storage gate disposed at an intersection between the gate pattern and the active region, the charge storage gate including a top surface, a side surface and a bottom surface;
a charge storage metal layer interposed between the side surface of the charge storage gate and the gate pattern; and
an intergate dielectric layer disposed between the top surface of the charge storage gate and the gate pattern, between the charge storage metal layer on the side surface of the charge storage gate and the gate pattern, and between the device isolation layer and the gate pattern.

2. The flash memory device of claim 1, wherein the charge storage gate includes an upper region having a first width and a lower region having a second width, and the first width is narrower than the second width.

3. The flash memory device of claim 2, wherein the first width and the second width extend in a direction crossed by the active region.

4. The flash memory device of claim 2, wherein the charge storage metal layer is disposed on a portion of the side surface of the charge storage gate that corresponds to the upper region.

5. The flash memory device of claim 2, wherein the first width is equal to, or smaller than, two times a distance that a depletion region is from a surface of the charge storage gate.

6. The flash memory device of claim 1, wherein the charge storage gate includes an upper region and a lower region having a same width.

7. The flash memory device of claim 1, wherein the charge storage gate includes silicon and the charge storage metal layer includes a pure metal or a metal silicide material.

8. The flash memory device of claim 7, wherein the charge storage metal layer includes a material having a work function equal to or greater than about 4 eV.

9. The flash memory device of claim 1, wherein the charge storage metal layer extends to the top surface of the charge storage gate.

10. The flash memory device of claim 1, wherein the charge storage metal layer extends to the bottom surface of the charge storage gate.

11. The flash memory device of claim 1, further comprising a gate insulating layer between the substrate and the charge storage gate.

12. A flash memory device, comprising:
a substrate having a plurality of active regions, a device isolation region being interposed between adjacent active regions; and
a gate pattern formed over the plurality of the active regions,
each of the active regions having a charge storage gate formed between the gate pattern and an upper surface of the active region, the charge storage gate having an upper surface, side surfaces and a lower surface,
a charge storage metal layer between the side surfaces of the charge storage gate and the gate pattern, and
an intergate dielectric layer formed over the upper surface of the charge storage gate, the charge storage metal layer and the device isolation layer, the gate pattern being formed over the integrate dielectric layer.

13. The flash memory device of claim 12, wherein the device isolation region defines the active region.

14. The flash memory device of claim 12, wherein the gate pattern extends across the active region.

15. The flash memory device of claim 12, wherein the charge storage gate is formed at an intersection between the gate pattern and the active region.

16. The flash memory device of claim 12, wherein the intergate dielectric layer is disposed between the top surface of the charge storage gate and the gate pattern, between the charge storage metal layer on the side surface of the charge storage gate and the gate pattern, and between the device isolation layer and the gate pattern.

17-25. (canceled)

26. A charge gate structure, comprising:
a charge storage gate formed over an active region, the charge storage gate having scalloped sides and including an upper region having a first width and a lower region having a second width, the first width being less than the second width; and
a charge storage metal layer formed over the scalloped sides of the charge storage gate.

27. The charge gate structure of claim 26, wherein the first width and the second width intersect the active region.

28. The charge gate structure of claim 26, wherein the charge storage gate includes silicon and the charge storage metal layer includes a pure metal or a metal silicide material.

29. The charge gate structure of claim 26, wherein the charge storage metal layer includes a material having a work function equal to, or greater than, about 4 eV.
